(19) United States
(12) Patent Application Publication
(10) Pub. No.: US 2026/0090348 A1
(43) Pub. Date: Mar. 26, 2026

(54) SEMICONDUCTOR STRUCTURE AND METHOD FOR FORMING THE SAME

(71) Applicant: Vanguard International Semiconductor Corporation, Hsinchu (TW)

(72) Inventors: Ya-Han Liang, Taoyuan City (TW); Po-Hao Chiu, Kaohsiung City (TW); Ching-Yi Hsu, Hsinchu City (TW); Po-Sheng Hu, Hsinchu City (TW); Chih-Hung Lin, Taichung City (TW)

(73) Assignee: Vanguard International Semiconductor Corporation, Hsinchu (TW)

(21) Appl. No.: 18/892,496

(22) Filed: Sep. 22, 2024

(51) Int. Cl. H01L 21/762

(52) U.S. Cl. CPC H10W 10/17; H10W 10/0148

(57) ABSTRACT

A semiconductor structure includes a substrate of a first conductive type, a device region including an active element and covering a portion of the substrate, and a trench region including a trench structure and in direct contact with the device region and with the substrate. The trench structure includes a bottom-filling material, a top-filling material covering the bottom-filling material, and a shield spacer surrounding the bottom-filling material and the top-filling material. There is a discontinuous grain interface disposed between the bottom-filling material and the top-filling material.

### BACKGROUND OF THE INVENTION

### 1. Field of the Invention

The present disclosure relates to a semiconductor structure and a method for forming the semiconductor structure, and in particular to a semiconductor structure having a deep trench structure and a method for forming the semiconductor structure.

### 2. Description of the Prior Art

In the process of manufacturing a conventional semiconductor structure, it is needed to form a variety of doped regions with different dopants and different dopant concentrations in the semiconductor structure. In a subsequent high-temperature process, the dopants in the doped region will diffuse to the periphery regions to result in an undesirable doping phenomenon, which is called lateral boron self-doping and lateral boron diffusion.

The current solution is to introduce a new mask for protecting the semiconductor device regions from the disturbance or influence of the lateral boron self-doping and lateral boron diffusion. However, this solution involves additional process steps of the mask formation and of the mask removal, which not only increases the complexity of the process but also increases the production cost.

In view of these, a novel semiconductor structure and an innovative method for forming the semiconductor structure are still greatly needed in the art to suppress the problems of the boron self-doping and of the lateral boron diffusion during high-temperature processes. At the same time, this novel semiconductor structure and innovative method for forming the semiconductor structure neither simplify the process by adding process masks nor increase the production costs, and they may also reduce process deviations to further maintain the performance and reliability of semiconductor devices.

### SUMMARY OF THE INVENTION

The present disclosure therefore proposes a semiconductor structure and a method for forming the semiconductor structure to suppress the problems of the boron self-doping and of the lateral boron diffusion during the high temperature processes. In the process of fabricating semiconductor structures, by introducing a top-filling material of a very low dopant concentration to cap a bottom-filling material of a high dopant concentration, it may reduce or slow down the disturbance or influences on adjacent regions due to the auto-doping of dopants in adjacent regions. The method for forming a semiconductor structure proposed by the present disclosure does not require the introduction of a process mask, so it not only reduces the complexity and production cost of the process, but also reduces the process deviations, thereby advantageously maintaining the performance and reliability of the produced semiconductor structure.

According to an embodiment of the present disclosure, a semiconductor structure is provided. The semiconductor structure includes a substrate, a device region and a trench region. The substrate has a first conductivity type. The device region includes an active component and covers a portion of the substrate. The trench region includes a trench structure and in direct contact with the device region and with the substrate. The trench structure includes a bottom-filling material, a top-filling material covering the bottom-filling material and a shield spacer surrounding the bottom-filling material and the top-filling material. There is a discontinuous grain interface disposed between the bottom-filling material and the top-filling material.

According to another embodiment of the present disclosure, a method for forming a semiconductor structure is provided to include the following steps. First, a substrate structure is provided. The substrate structure includes a substrate, a device region covering a portion of the substrate, and a trench region in direct contact with the device region and with the substrate. The trench region includes a trench structure, the trench structure includes a trench, a bottom-filling material filling up the trench and a spacer filling the trench and surrounding the bottom-filling material. Second, a first etching step is carried out to form a buffer space located in the trench and exposing an inclined wall configuration of the spacer. Next, a dielectric layer is formed to fill the buffer space, and cover the device region, the bottom-filling material and the inclined wall configuration. Then, the dielectric layer covering device region is selectively removed. Afterwards, a top-filling material is formed to fill the buffer space and cover the device region, the bottom-filling material and the inclined wall configuration. Subsequently, the top-filling material is selectively removed so that the top-filling material fills up the buffer space. There is a discontinuous grain interface disposed between the top-filling material and the bottom-filling material.

In order to make the features of the present disclosure clear and easily understood, embodiments are given below and described in detail with reference to the accompanying drawings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 illustrates a schematic cross-sectional view of lateral boron self-doping and lateral boron diffusion in a semiconductor trench structure according to an embodiment of the present disclosure.

FIG. 2 to FIG. 6 illustrate some schematic cross-sectional views of various process stages of a method for forming a semiconductor structure according to an embodiment of the present disclosure.

FIG. 7 is a schematic cross-sectional view of a semiconductor device according to an embodiment of the present disclosure.

FIG. 8 is a schematic cross-sectional view of a semiconductor device according to a variant embodiment of the present disclosure.

FIG. 9 is a schematic top view of a semiconductor device according to an embodiment of the present disclosure.

### DETAILED DESCRIPTION

The present disclosure provides several different embodiments which may be used to enable different features of the present disclosure. To simplify the explanation, some examples of specific components and arrangements are also described in this disclosure. These examples are provided for illustrative purposes only and are not intended to be limitations in any way. For example, the following description of “the first feature is formed on or above the second feature” may mean “the first feature is in direct contact with the second feature” or “there are other features between the features so that the first feature and the second feature are not in direct contact with each other”. Additionally, various embodiments in the present disclosure may use repeated reference symbols and/or wordings. These repeated reference symbols and wordings are used to make the description more concise and clear, but are not used to indicate the correlation between different embodiments and/or configurations.

In addition, for the space-related wordings mentioned in this disclosure, for example: “under”, “low”, “beneath”, “above”, “on”, “upper”, “top”, “bottom” and similar words are used to describe the relative relationship between one element or feature and another (or multiple) elements or features in the drawings for the convenience of description. In addition to the orientations shown in the drawings, these spatially related terms are also used to describe possible orientations of the semiconductor device during use and operation. As a semiconductor device is oriented differently (rotated 90 degrees or other orientations), the spatially related description used to describe the orientation should be interpreted in a similar manner.

Although this disclosure uses terms such as first, second, third, etc. to describe various elements, components, regions, layers, and/or sections, it should be understood that these elements, components, regions, layers, and/or sections should not be limited by these terms. These terms are only used to distinguish one element, component, region, layer, and/or section from another element, component, region, layer, and/or section, and they neither imply or represent the element with a previous serial number, nor represent the order of arrangement of one component with another component, or the order of the manufacturing method. Therefore, a first element, component, region, layer, or section used below may also be termed a second element, component, region, layer, or section without departing from the scope of the specific embodiments of the present disclosure.

Terms “about” or “substantially” used in this disclosure generally mean within 20%, preferably within 10%, and more preferably within 5% of a given value or range, or within 3%, or within 2%, or within 1%, or within 0.5%. It should be noted that the quantities provided in the specification are approximate quantities, that is, even without specifically stating “approximately” or “substantially”, the meaning of “approximately”or “substantially”may still be implied.

The terms “couple”, “coupling” and “electrical connection” mentioned in this disclosure include any direct and indirect electrical connection means. For example, if a first component is coupled to a second component, it means that the first component may be directly electrically connected to the second component, or indirectly electrically connected to the second component via other devices or connections.

Although the invention of the present disclosure is described below through specific embodiments, the inventive principles of the present disclosure may also be applied to other embodiments. In addition, in order not to obscure the spirit of the present disclosure, specific details are omitted, and these omitted details fall within the scope of knowledge of those with ordinary skill in the art.

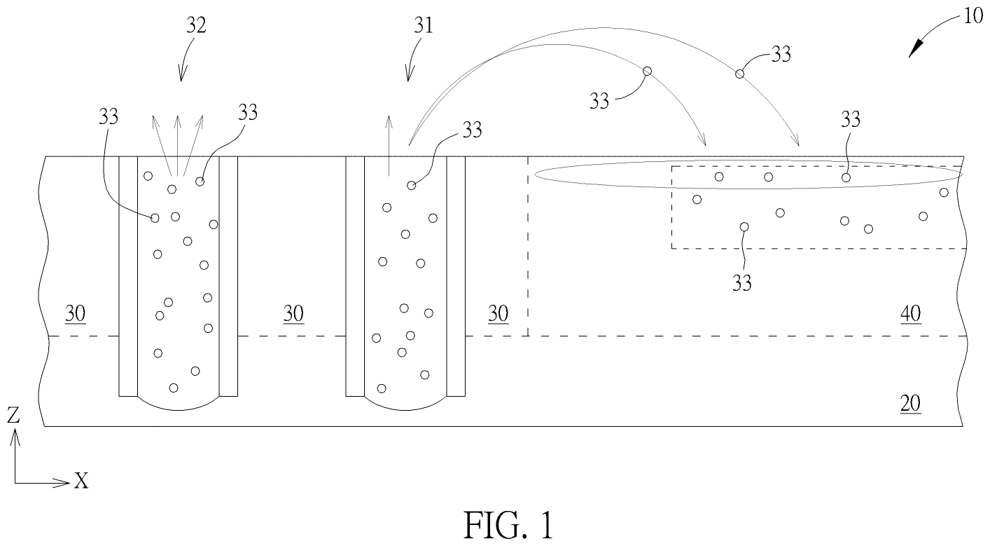

FIG. 1 illustrates a schematic cross-sectional view of the lateral boron self-doping and of the lateral boron diffusion in a semiconductor trench structure according to an embodiment of the present disclosure. The semiconductor structure 10 includes a semiconductor substrate 20, a semiconductor trench region 30 and a semiconductor device region 40. The semiconductor trench region 30 includes semiconductor trenches, such as a first semiconductor trench 31 and a second semiconductor trench 32. The semiconductor trenches are filled with a semiconductor material and dopants 33, such as boron. There may be a plurality of device regions in the semiconductor device region 40, and each device region may have different intrinsic dopants to correspond to different intrinsic dopant concentrations.

Since the semiconductor trenches are filled with a semiconductor material and dopants 33, driven by a high temperature, the dopants 33 in the semiconductor trench region 30 may actively migrate and diffuse to the peripheral regions when the semiconductor structure 10 is subjected to a high-temperature process. Therefore, the electrical properties of the adjacent regions are prone to the interference or influence of the lateral boron self-doping and of the lateral boron diffusion from the semiconductor trench region 30, which not only directly increases the process deviations, but also indirectly jeopardizes the performance and reliability of the semiconductor structure 10.

In order to further address the problems of the boron self-doping and of the lateral boron diffusion which occur in the above embodiments, the present disclosure further provides a semiconductor structure and a method for forming the semiconductor structure. The corresponding embodiments are described in detail below.

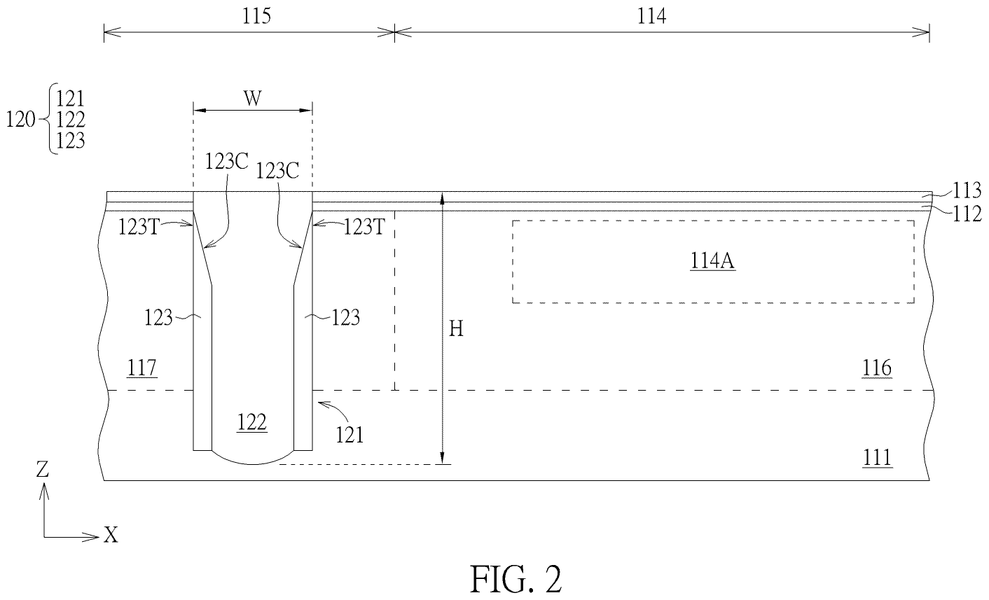

FIG. 2 to FIG. 6 illustrate some schematic cross-sectional views of some process stages of a method for forming a semiconductor structure according to an embodiment of the present disclosure. The semiconductor structure produced in this embodiment may suppress the problems of the boron self-doping and of the lateral boron diffusion during a high temperature process. As shown in FIG. 2, in the step shown in FIG. 2, first a substrate structure 110 is provided. The substrate structure 110 may be a composite substrate of a semiconductor material, such as a silicon-on-insulator (SOI) substrate. For example, the substrate structure 110 may be composed of a substrate 111, an oxide layer 112, and a nitride layer 113 from bottom to top along the Z-direction. The nitride layer 113 directly covers the oxide layer 112, and the oxide layer 112 directly covers the substrate 111.

The substrate 111 may include a single material or a compound material of a semiconductor element, and be doped to have a first conductivity type, such as a P-type doped substrate. The elemental materials of the semiconductor elements may be, for example, single crystal silicon or polycrystalline silicon, and the compound material of the semiconductor element may be, for example, silicon carbide or gallium nitride. The elemental materials and compound materials may come from wafers, and the wafers may be obtained by carrying out a crystal growth method. The oxide layer 112 may include an insulating material, such as silicon oxide, to entirely cover the surface of the substrate 111. The nitride layer 113 may include an insulating material, such as silicon nitride, for example, to entirely cover the surface of the oxide layer 112. The silicon oxide layer of the oxide layer 112 and the silicon nitride layer of the nitride layer 113 may be formed by, for example, a chemical vapor deposition (chemical vapor deposition, CVD) method, a plasma-enhanced chemical vapor deposition (plasma-enhanced CVD, PECVD) method, respectively, or by an atomic layer deposition (ALD) method. The oxide layer 112 and the nitride layer 113 may respectively have an appropriate thickness.

According to an embodiment, the substrate structure 110 further includes a substrate 111, a device region 114 and a trench region 115. The device region 114 covers a portion of the substrate 111 and has the dopants the same as the first conductivity type or a different type of dopants, such as a P-type doped device region or an N-type doped device region. The device region 114 may be used to set a variety of components of the active component 114A, such as at least one of the doped region, the gate trench or the metal field plate for a high voltage device (HV), for a medium voltage device (MV), and for a low voltage device (LV). At this point in the process, the device region 114 may only include the doped region of the active device 114A, but the metal field plate has not yet been formed, depending on actual requirements. The high-voltage components, medium-voltage components, and low-voltage components are active components well known in the art, so the details are not elaborated here.

The trench region 115 directly contacts the device region 114 and the substrate 111. For example, the trench region 115 and the device region 114 are juxtaposed in the X-direction and cover the substrate 111. The trench region 115 includes one or more trench structures 120, such as deep trench structures. According to an embodiment, each trench structure 120 includes a trench 121, a bottom-filling material 122 and a spacer 123. The trench 121 penetrates deeply into the substrate 111 along the Z-direction from the surface of the substrate structure 110 and has an appropriate trench height H and trench width W, so that the trench 121 has an appropriate aspect ratio (H/W), such as a height-to-width ratio greater than 20. The bottom-filling material 122 may include an elemental material or a compound material of a semiconductor element, doped with a first conductive type of a high dopant concentration, such as P-type doped polycrystalline silicon with boron, and fills up the trench 121.

The spacer 123 may be an insulating material. The insulating material may be, for example, silicon oxide, silicon nitride, or a combination thereof, fills the trench 121 and surrounds the bottom-filling material 122 to serve as an insulation layer between the bottom-filling material 122 and the substrate structure 110. According to an embodiment, the spacer 123 may not completely cover the inner wall of the trench 121 to expose a portion of the substrate 110, so that the spacer 123 may be sandwiched outside the substrate structure 110 and the bottom-filling material 122, and a portion of the bottom-filling material 122 may also be in direct contact with the substrate structure 110. According to another embodiment, the spacer 123 has an inclined wall configuration 123C. For example, the inclined wall configuration 123C of the spacer 123 includes a top tip 123T. According to another embodiment, the inclined wall configuration 123C of the spacer 123 is not limited to a flat surface, but may also be arc-shaped.

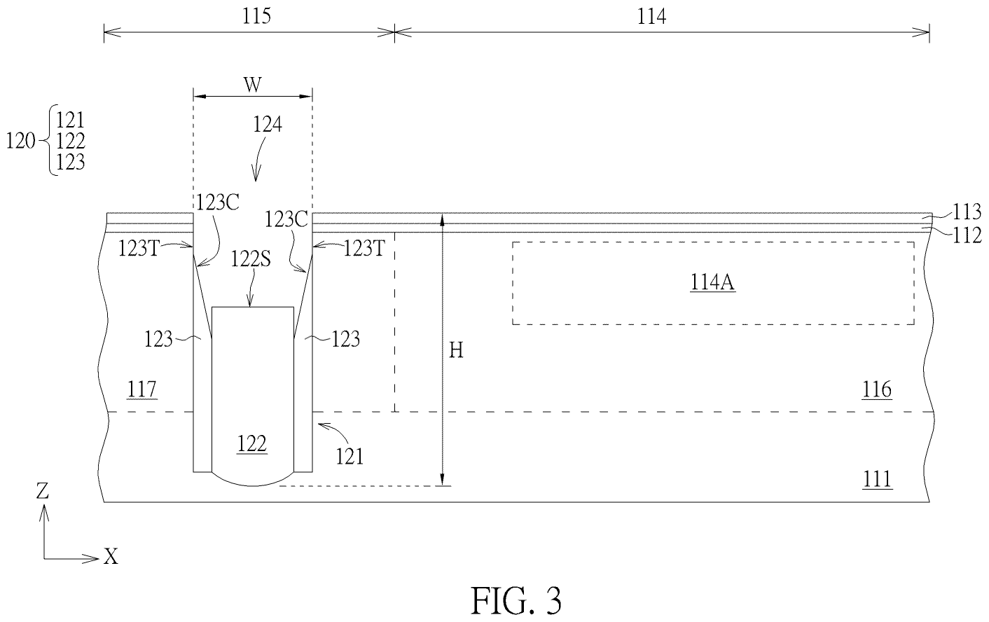

Next, as shown in FIG. 3, in the step shown in FIG. 3, a first etching step is carried out to form a buffer space 124 at the top of the trench 121. The first etching step may be a dry etching method with etching selectivity on polysilicon, so that the first etching step may preferably selectively remove the polysilicon, allowing the buffer space 124 to penetrate deeply into the trench 121, lowering the top surface 122S of the bottom-filling material 122, and exposing the top tip 123T of the inclined wall configuration 123C. The first etching step may also reduce the influences on the spacer 123, on the oxide layer 112 and the nitride layer 113. The buffer space 124 which is formed after the first etching step has a buffer depth D along the Z-direction. According to an embodiment, the buffer depth D is 0.01%˜90% of the trench height H of the trench 121, in other words, 0.01%≤D/H≤90%.

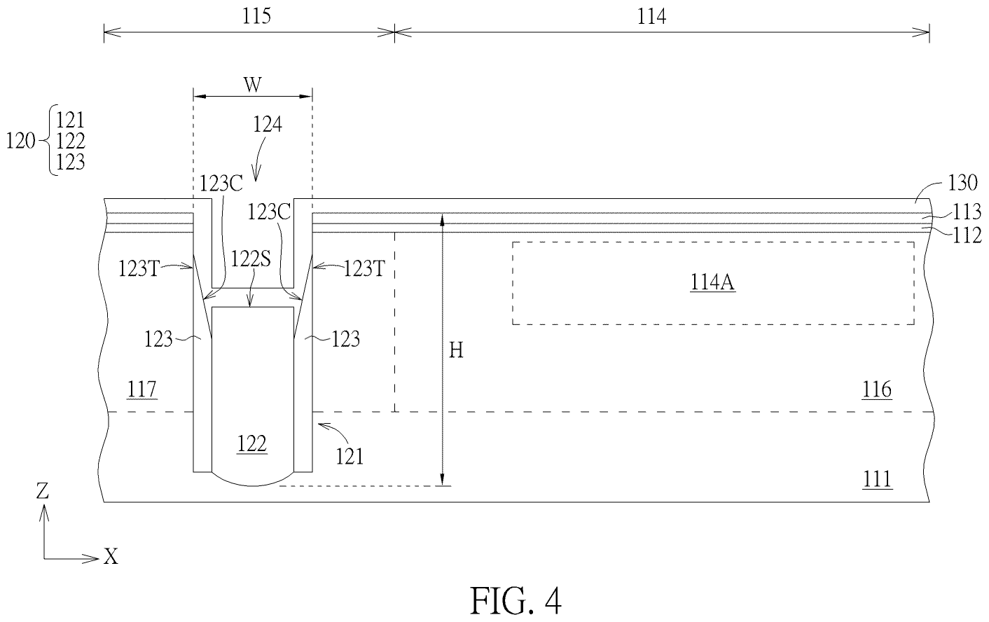

Then, as shown in FIG. 4, in the step shown in FIG. 4, a dielectric layer 130 is formed. For example, the dielectric layer 130 is formed by a deposition method such as the chemical vapor deposition, the plasma enhanced chemical vapor deposition, or the atomic layer deposition. The dielectric layer 130 fills the buffer space 124 and conformally covers the inner wall of the trench 121, the device region 114, the trench region 115, the surface 122S of the bottom-filling material 122, and the inclined wall configuration 123C. For example, the dielectric layer 130 may be in direct contact with the top tip 123T of the inclined wall configuration 123C in a complementary manner. The dielectric layer 130 may be an insulating material, and the insulating material may be, for example, silicon oxide, silicon nitride or a combination thereof. According to an embodiment, the insulating material of the dielectric layer 130 may be the same as the insulating material of the spacer 123.

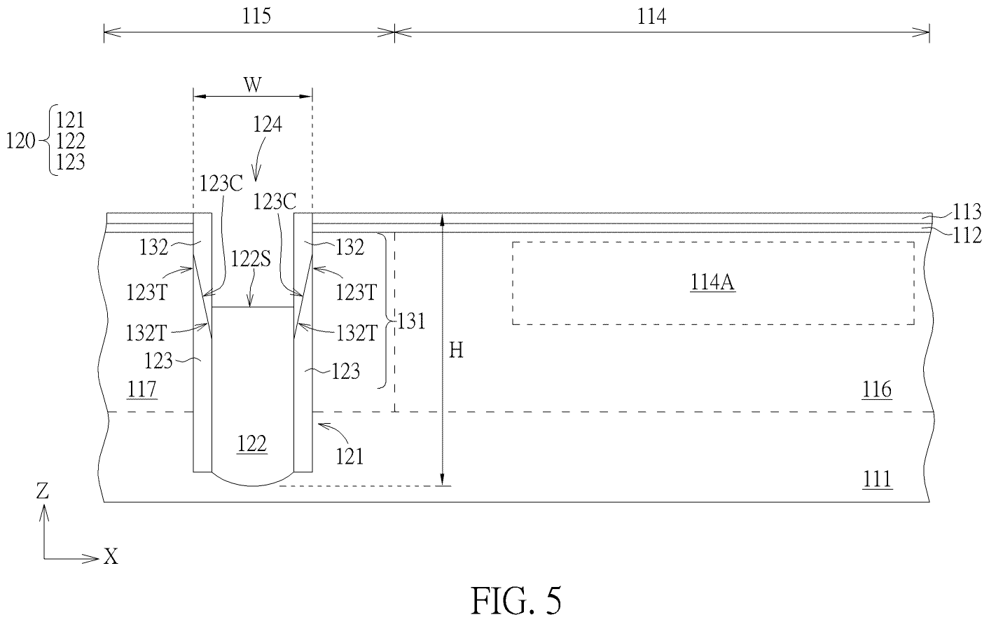

Next, as shown in FIG. 5, in the step shown in FIG. 5, the dielectric layer 130 covering the device region 114 and the trench region 115 is selectively removed. In other words, in this step, the dielectric layer 130 located in the buffer space 124 is selectively kept, that is, the dielectric layer 130 covering the inner wall of the trench 121 and the inclined wall configuration 123C is selectively kept. The removal method for selectively removing the dielectric layer 130 may be a dry etching method with etching selectivity on the insulating material of the dielectric layer 130 to selectively remove the dielectric layer 130 outside of the buffer space 124 and to keep the dielectric layer 130 in the buffer space 124 to be able to reduce the influences of the removal method on the oxide layer 112 and on the nitride layer 113. According to an embodiment, the removal method for selectively removing the dielectric layer 130 may include an anisotropic etching process, so that the dielectric layer 130 covering the device region 114 and the trench region 115 may be completely removed, the dielectric layer 130 covering the top surface 122S of the bottom-filling material 122 may be completely removed, and collaterally the height of the dielectric layer 130 in the buffer space 124 is slightly reduced.

According to an embodiment, the dielectric layer 130 after the removal method has a tip configuration along the Z-direction, and forms a shield spacer 131 together with the spacer 123. For example, the tip configuration of the dielectric layer 130 is complementarily in direct contact with the top tip 123T of the inclined wall configuration 123C, so that the dielectric layer 130 penetrates deeply into the inclined wall configuration 123, forming an engaging configuration with the top tip 123T of the inclined wall configuration 123C. The shield spacer 131 includes an upper shield spacer 132 from the dielectric layer 130, and a lower shield spacer 123 from the spacer 123. According to another embodiment, the top tip 123T of the lower shield spacer 123 formed by the top tip 123T of the inclined wall configuration 123C of the spacer 123 is not only higher than the bottom tip 132T of the upper shield spacer 132 but also higher than the top surface 122S of the bottom-filling material 122.

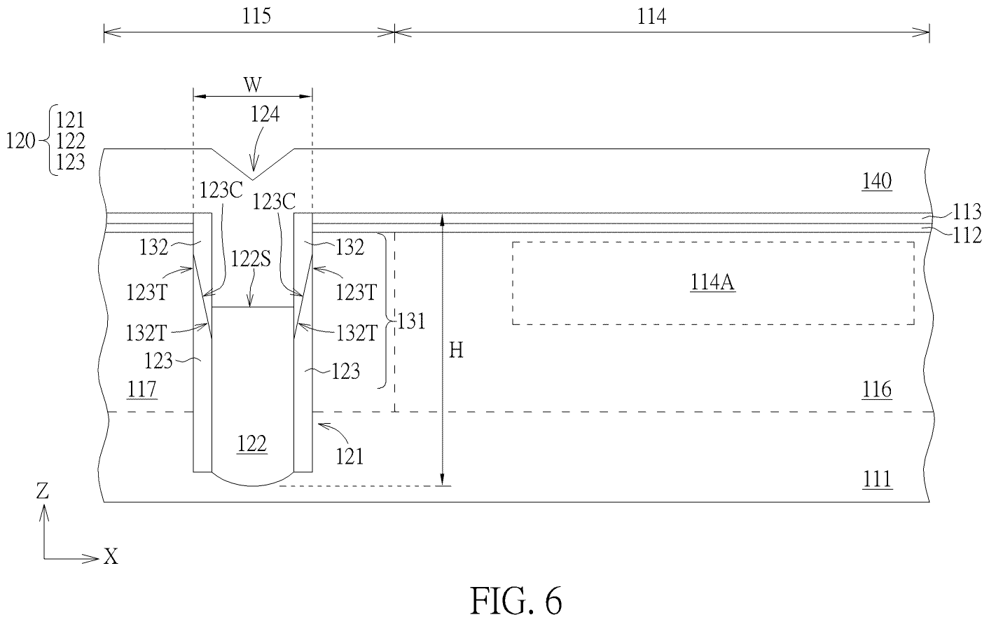

To be continued, as shown in FIG. 6, a top-filling material 140 is formed. The resultant top-filling material 140 fills the buffer space 124 and conformally covers the device region 114, the trench region 115, the top surface 122S of the bottom-filling material 122 and the inclined wall configuration 123C. The top-filling material 140 may include an elemental material or a compound material of a semiconductor element, such as polycrystalline silicon. According to an embodiment, the semiconductor material of the top-filling material 140 may be the same as the semiconductor material of the bottom-filling material 122. However, the difference between the top-filling material 140 and the bottom-filling material 122 resides in the different embodiments of the dopants in the top-filling material 140. According to an embodiment, there may be no dopant in the top-filling material 140 and the top-filling material 140 may be composed of a single material of a semiconductor element.

Alternatively, according to another embodiment, the surface of the top-filling material 140 has a top dopant concentration, and any part of the bottom-filling material 122 has a bottom dopant concentration. The top dopant concentration on the surface of the top-filling material 140 may be extremely low; for example, the top dopant concentration is less than 10%, less than 5%, less than 1%, less than 0.1%, or less than 0.01% of the bottom dopant concentration. Because the top dopant concentration on the surface of the top-filling material 140 is significantly lower than the bottom dopant concentration in the bottom-filling material, it may also be considered that the surface 140S of the top-filling material 140 substantially has no top dopant concentration compared with the bottom filling material.

Alternatively, according to another embodiment, the bottom-filling material 122 has a bottom average dopant concentration, the top-filling material 140 has a top average dopant concentration, and the bottom average dopant concentration of the bottom-filling material 122 is higher than the top average dopant concentration of the top-filling material 140. Because the dopants in either the bottom-filling material 122 or in the top-filling material 140 may not be evenly distributed, the concept of an average dopant concentration may be used to represent the substantial dopant concentration therein. The calculation of the average dopant concentration may be determined by the ratio of the total dopant amount in the given filling material to the total volume of the given filling material.

Alternatively, according to still another embodiment, the top-filling material 140 may have dopants. For example, the bottom-filling material 122 and the top-filling material 140 respectively have the dopants of the first conductivity type, but the dopant concentration of the top-filling material 140 is lower. According to an embodiment, the top-filling material 140 includes an upper region 141 and a lower region 142 such that the upper region 141 caps the lower region 142. The ratio of the upper average dopant concentration of the upper region 141 to the lower average dopant concentration of the lower region 142 is less than 20%.

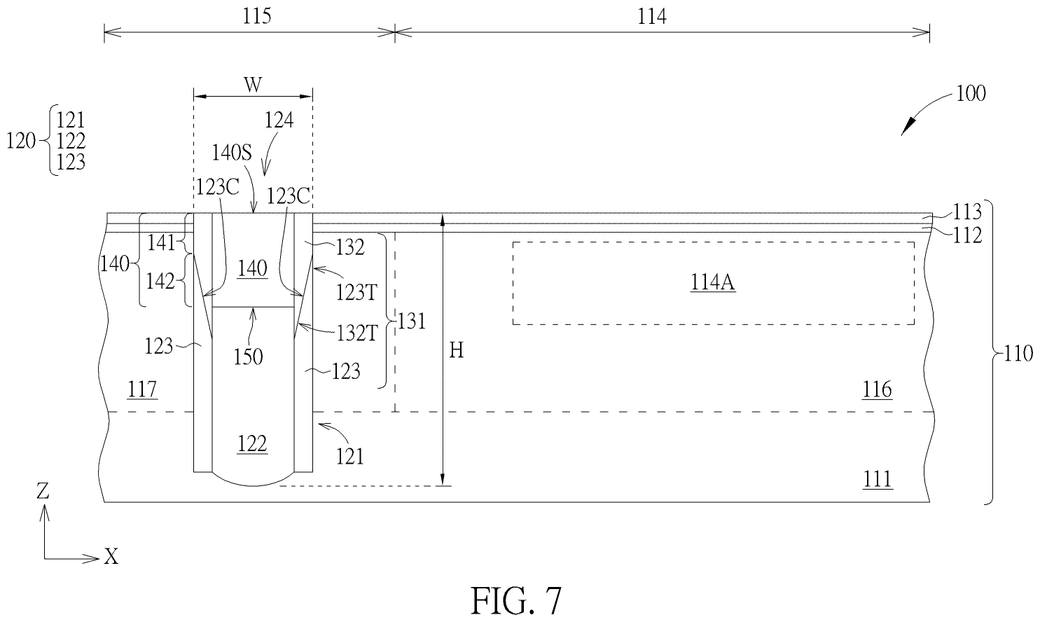

Next, as shown in FIG. 7, the excess top-filling material 140 is selectively removed. For example, the chemical mechanical polishing is used to selectively remove the top-filling material 140 covering the nitride layer 113 which serves as a polishing stop layer, so that the top-filling material 140 selectively fills up the buffer space 124 to obtain a semiconductor structure 100. According to one embodiment, there is a discontinuous grain interface 150 disposed between the top-filling material 140 and the bottom-filling material 122. The discontinuous grain interface indicates that the top-filling material 140 and the bottom-filling material 122 each has its own lattice configuration. The lattice configurations of the two may be the same or different. Even though the lattice configurations of the two may be the same, a discontinuous grain interface 150 and/or a discontinuous dopant concentration may be observed between the top-filling material 140 and the bottom-filling material 122 because the top-filling material 140 and the bottom-filling material 122 are separately formed.

Optionally a high-temperature process may be carried out in the device region 114 after the top-filling material 140 is selectively removed. The high-temperature process may be any semiconductor process with a temperature exceeding 1000° C. Since the top-filling material 140 with a lower dopant concentration cap atop the bottom-filling material 122 with a higher dopant concentration and buffers the dopant diffusion from the bottom-filling material 122, the presence of the top-filling material 140 may prevent the dopants in the bottom-filling material 122, which has a high dopant concentration, from actively doping and laterally diffusing into the device region 114, driven by the high-temperature process. After the high-temperature process, dopant concentration gradients may be respectively formed in the top-filling material 140 and in the bottom-filling material 122. For example, according to one embodiment, the top-filling material 140 has a dopant concentration gradient which decreases in a direction away from bottom-filling material 122. Alternatively, according to another embodiment, the bottom-filling material 122 has a dopant concentration gradient which decreases in a direction toward the top-filling material 140.

After the above steps, as shown in FIG. 7, the semiconductor structure 100 of the present disclosure may be obtained. FIG. 7 is a schematic cross-sectional view of a semiconductor device 100 according to an embodiment of the present disclosure. The semiconductor structure 100 includes a substrate structure 110, a device region 114, and a trench region 115. The substrate structure 110 may be a composite substrate of semiconductor materials, such as a silicon on insulator (SOI) substrate. For the details of the substrate structure 110, the substrate 111, the oxide layer 112, the nitride layer 113, the device region 114, and the trench region 115 . . . etc., please refer to the corresponding descriptions in FIG. 2 through FIG. 6 The device region 114 and the trench region 115 respectively include a first doped region 116 and a second doped region 117. For example, the device region 114 includes the first doped region 116 and the trench region 115 includes the second doped region 117, or the device region 114 includes the second doped region 117 and the trench region 115 includes the first doped region 116. The first doped region 116 is disposed on the substrate 111 and has a first conductivity type, and the second doped region 117 is disposed on the substrate 111 and has a second conductivity type. The first conductivity type and the second conductivity type are different conductivity types formed by different dopants. For example, the first conductivity type is P-type formed by doping Group III elements, and the second conductivity type is N-type formed by doping Group V elements.

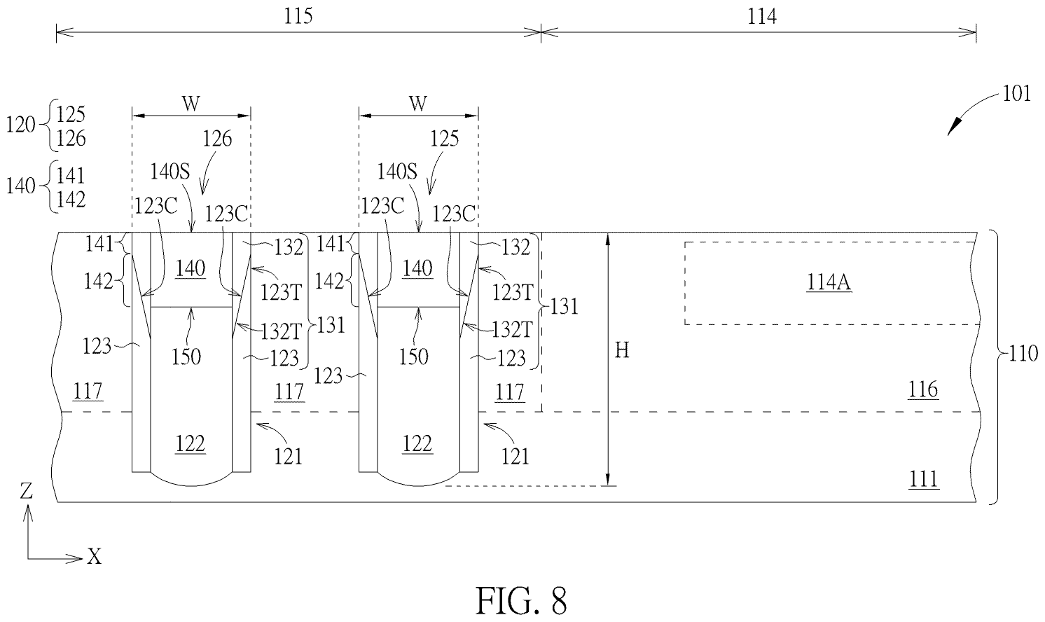

The trench region 115 includes one or more trench structures 120, also known as deep trench structures. The trench structure 120 penetrates the second doped region 117 and extends to the substrate 111. FIG. 8 is a schematic cross-sectional view of a semiconductor device 101 according to a variant embodiment of the present disclosure. The trench region 115 in the semiconductor structure 101 may include two trench structures, such as a first trench structure 125 and a second trench structure 126. According to an embodiment, each trench structure includes a trench 121, a bottom-filling material 122, a top-filling material 140 and a shield spacer 131. The trench 121 has an appropriate trench height H and trench width W, so that the trench 121 has an appropriate aspect ratio (H/W), for example, an aspect ratio greater than 20. The bottom-filling material 122 is electrically connected to the substrate 111. Please refer to the above descriptions for the details of the trench 121, of the bottom-filling material 122, of the top-filling material 140, and of the shield spacer 131 . . . etc. in the trench structure.

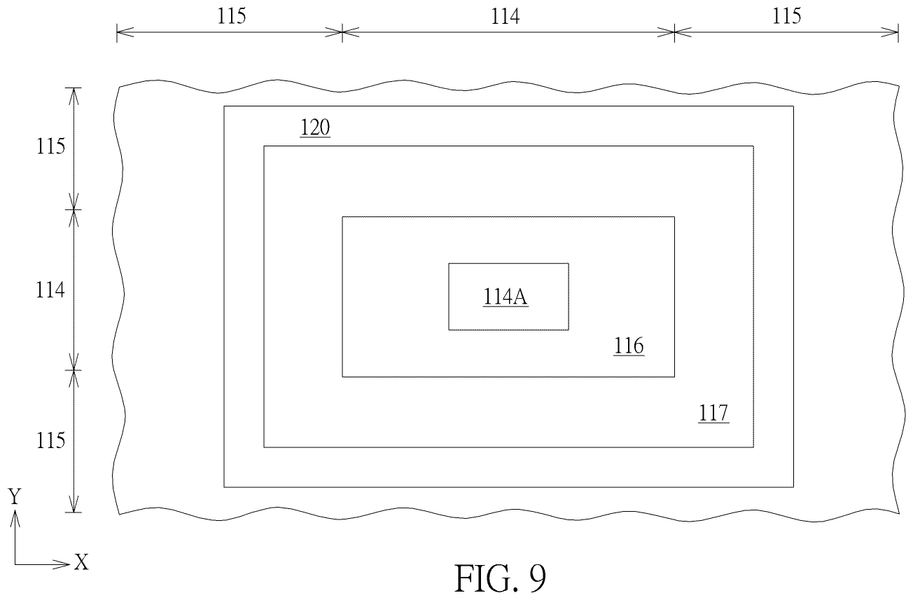

FIG. 9 is a schematic top view of the semiconductor device 101 according to an embodiment of the present disclosure. In a top view, the trench structures 120 are arranged to surround the active device 114A disposed in the device region 114.

As shown in FIG. 7, the shield spacer 131 includes a top tip 123T of an insulating material and a bottom tip 132T of an insulating material. The insulating material may be, for example, silicon oxide, silicon nitride, or a combination thereof. The top tip 123T and the bottom tip 132T of the inclined wall configuration 123C may, for example, be complementarily in direct contact with each other to form an engaging configuration together. The shield spacer 131 includes an upper shield spacer 132 and a lower shield spacer 123. According to one embodiment, the top tip 123T of the lower shield spacer 123 is not only higher than the bottom tip 132T of the upper shield spacer 132 but also higher than the top surface 122S of the bottom-filling material 122. In other words, the bottom tip 132T of the upper shield spacer 132 is lower than the top tip 123T of the lower shield spacer 123.

The top-filling material 140 fills the buffer space 124 while completely caps the top surface 122S of the bottom-filling material 122. According to an embodiment, the top-filling material 140 and the bottom-filling material 122 may include the same or different semiconductor materials. However, the difference between the top-filling material 140 and the bottom-filling material 122 resides in the different embodiments of the dopants of the top-filling material 140. According to an example, the top-filling material 140 may not have the dopants, and may consist of a single material of the semiconductor elements.

Alternatively, according to another example, the surface 140S of the top-filling material 140 has a top dopant concentration and any part of the bottom-filling material 122 has a bottom dopant concentration. The top dopant concentration on the surface 140S of the top-filling material 140 may be extremely low and it may be considered that the surface 140S of the top-filling material 140 substantially has no top dopant concentration in comparison with the bottom dopant concentration.

Alternatively, according to another embodiment, the bottom-filling material 122 has a bottom average dopant concentration, the top-filling material 140 has a top average dopant concentration, and the bottom average dopant concentration of the bottom-filling material 122 is higher than the top average dopant concentration of the top-filling material 140.

Alternatively, according to still another example, the top-filling material 140 may have the dopants. For example, the bottom-filling material 122 and the top-filling material 140 respectively have the dopants of the first conductivity type, but the distribution of the dopant concentration of the top-filling material 140 is lower. According to an embodiment, the top-filling material 140 includes an upper region 141 and a lower region 142 such that the upper region 141 caps the lower region 142. The ratio of the upper average dopant concentration of the upper region 141 to the lower average dopant concentration of the lower region 142 is less than 20%.

According to one embodiment, there is a discontinuous grain interface 150 and/or a discontinuous dopant concentration disposed between the top-filling material 140 and the bottom-filling material 122. For example, the top-filling material 140 has a top dopant concentration gradient and the bottom-filling material 122 has a bottom dopant concentration gradient. The top dopant concentration gradient and the bottom dopant concentration gradient become a discontinuous dopant concentration due to the discontinuous grain interface 150. Regarding the shield spacer 131 adjacent to the discontinuous grain interface 150, the top tip 123T of the lower shield spacer 123 and the bottom tip 132T of the upper shield spacer 132 may form a discontinuous inclined wall combination, that is, the inclined wall of the top tip 123T and the inclined wall of the bottom tip 132T face each other to form a combination.

There are respective dopant concentration gradients formed in the top-filling material 140 and in the bottom-filling material 122. For example, according to one embodiment, the top-filling material 140 has a top dopant concentration gradient which decreases in a direction away from bottom-filling material 122. Alternatively, according to another embodiment, the bottom-filling material 122 has a bottom dopant concentration gradient which decreases in a direction toward the top-filling material 140.

The semiconductor structures and the method for forming the semiconductor structure in the present disclosure may suppress the problems of the boron self-doping and of the lateral boron diffusion during the high temperature processes. By introducing an additional top-filling material to cap the bottom-filling material with a high dopant concentration in the processes of fabricating the semiconductor structures, it is able to reduce or slow down the interference or the influences on the adjacent regions caused by the automatic doping of the dopants to the adjacent regions during the method of forming a semiconductor structure. In the present disclosure the method for forming the semiconductor structures may reduce the complexity and the production cost of the processes because no additional process mask is required, and may further reduce the process deviations, thereby advantageously maintaining the performance and reliability of the semiconductor structures thus produced.

Those skilled in the art will readily observe that numerous modifications and alterations of the device and method may be made while retaining the teachings of the invention.

Accordingly, the above disclosure should be construed as limited only by the metes and bounds of the appended claims.

What is claimed is:

1. A semiconductor structure, comprising:
a substrate of a first conductive type;
a device region comprising an active element and covering a portion of the substrate; and
a trench region comprising a trench structure and directly contacting the device region and the substrate, wherein the trench structure comprises a bottom-filling material, a top-filling material covering the bottom-filling material, and a shield spacer surrounding the bottom-filling material and the top-filling material, and there is a discontinuous grain interface disposed between the bottom-filling material and the top-filling material.

2. The semiconductor structure of claim 1, wherein the bottom-filling material and the top-filling material respectively have the first conductivity type, and a bottom average dopant concentration of the bottom-filling material is higher than a top average dopant concentration of the top-filling material.

3. The semiconductor structure of claim 1, wherein the top-filling material includes an upper region and a lower region, and a ratio of an upper average dopant concentration of the upper region over a lower average dopant concentration of the lower region is less than 20%.

4. The semiconductor structure of claim 1, wherein the bottom-filling material is electrically connected to the substrate.

5. The semiconductor structure of claim 1, wherein the top-filling material has a dopant concentration gradient which decreases in a direction away from the bottom-filling material.

6. The semiconductor structure of claim 1, wherein the bottom-filling material has a dopant concentration gradient which decreases in a direction toward the top-filling material.

7. The semiconductor structure of claim 1, wherein the top-filling material and the bottom-filling material comprise a same semiconductor material.

8. The semiconductor structure of claim 1, wherein the top-filling material covers an entire top surface of the bottom-filling material.

9. The semiconductor structure of claim 1, wherein the shield spacer adjacent to the discontinuous grain interface has a discontinuous inclined wall combination.

10. The semiconductor structure of claim 9, wherein the shield spacer comprises a lower shield spacer and an upper shield spacer, and a top tip of the lower shield spacer is higher than a top surface of the bottom-filling material.

11. The semiconductor structure of claim 10, wherein a bottom tip of the upper shield spacer is lower than the top tip of the lower shield spacer.

12. The semiconductor structure of claim 1, wherein a composition of the shield spacer comprises an insulating material.

13. The semiconductor structure of claim 1, wherein the device region and the trench region respectively comprises a first doped region and a second doped region, and the second doped region is disposed on the substrate and has a second conductivity type, and the trench structure penetrates the second doped region.

14. The semiconductor structure of claim 1, wherein a height-to-width ratio of the trench structure is greater than 20.

15. The semiconductor structure of claim 1, wherein the trench structure surrounds the device region in a top view.

16. A method for forming a semiconductor structure, comprising:
providing a substrate structure, the substrate structure comprising a substrate, a device region covering a portion of the substrate, and a trench region in direct contact with the device region and with the substrate, wherein the trench region comprises a trench structure, and the trench structure comprises a trench, a bottom-filling material filling up the trench, and a spacer filling the trench and surrounding the bottom-filling material;
performing a first etching step to form a buffer space located in the trench and exposing an inclined wall configuration of the spacer;
forming a dielectric layer filling the buffer space and covering the device region, the bottom-filling material and the inclined wall configuration;
selectively removing the dielectric layer covering the device region;
forming a top-filling material filling the buffer space and covering the device region, the bottom-filling material and the inclined wall configuration; and
selectively removing the top-filling material so that the top-filling material fills up the buffer space, wherein there is a discontinuous grain interface disposed between the top-filling material and the bottom-filling material.

17. The method for forming a semiconductor structure of claim 16, wherein the bottom-filling material and the top-filling material respectively have a first conductivity type, and a bottom average dopant concentration of the bottom-filling material is higher than a top average dopant concentration of the top-filling material.

18. The method for forming a semiconductor structure of claim 16, wherein a top doping depth of the top-filling material filling up the buffer space is 0.01%˜90% of a trench height of the trench.

19. The method for forming a semiconductor structure of claim 16, wherein the dielectric layer penetrates into the inclined wall configuration to form an engaging configuration together with the inclined wall configuration.

20. The method for forming a semiconductor structure of claim 16, further comprising:
performing a high-temperature process with a temperature exceeding 1000° C. on the device region after selectively removing the top-filling material.
